(19) United States
(12) Patent Application Publication
(10) Pub. No.: US 2026/0075757 A1
(43) Pub. Date: Mar. 12, 2026

(54) MODULAR RADIATOR ASSEMBLY AND AIR-TO-LIQUID COOLING CABINET USING SAME

(71) Applicant: Delta Electronics, Inc., Taoyuan City (TW)

(72) Inventors: Kuan-Lung Wu, Taoyuan City (TW); Chen-Hsiu Lee, Taoyuan City (TW); Siang-Lin You, Taoyuan City (TW); Hung-Min Cho, Taoyuan City (TW)

(21) Appl. No.: 19/294,098

(22) Filed: Aug. 7, 2025

Related U.S. Application Data
(60) Provisional application No. 63/693,317, filed on Sep. 11, 2024.

(30) Foreign Application Priority Data
Jan. 23, 2025 (CN) 202510110229.9

(51) Int. Cl. H05K 7/20

(52) U.S. Cl. CPC H05K 7/20263; H05K 7/20172; H05K 7/20272

(57) ABSTRACT

A modular radiator assembly and an air-to-liquid cooling cabinet using the same are disclosed. The radiator assembly includes a housing, a heat exchanger module, two fan sets. The housing includes an air inlet, an air outlet, an upper wall, a lower wall and two lateral walls, and an accommodation space is in communication between the air inlet and the air outlet. The heat exchanger module is connected to the upper wall, the lower wall and the two lateral walls. The heat exchanger module is accommodated in the accommodation space obliquely relative to the lower wall. The two fan sets are connected between the two lateral walls, and disposed adjacent to the air inlet or the air outlet. An airflow generated by the two fan sets is inhaled through the air inlet, flows through the heat exchanger module, and is discharged from the air outlet.

### CROSS-REFERENCE TO RELATED APPLICATION

This application claims the benefit of U.S. Provisional Application No. 63/693,317 filed on Sep. 11, 2024, and entitled “RADIATOR MODELIZED DESIGN”. This application claims priority to China Patent Application No. 202510110229.9, filed on Jan. 23, 2025. The entireties of the above-mentioned patent application are incorporated herein by reference for all purposes.

### FIELD OF THE INVENTION

The present disclosure relates to a radiator assembly structure, and more particularly to a modular radiator assembly and an air-to-liquid cooling cabinet using the same to have the modular radiator assembly to be integrated and minimized, so that different numbers of modular radiator assemblies allows to be installed according to the customer's heat dissipation wattage requirements, thereby shortening the development time of the radiator and reducing the product cost and the development cost.

### BACKGROUND OF THE INVENTION

In the current market, the air-to-liquid (ATL) cooling solution provides the required heat dissipation wattage for customers, and the suppliers design the corresponding heat dissipation fins (i.e., the radiator) according to the requirements. However, for the different wattage heat dissipation requirements, different heat sink fins must be designed. In that, the commonality of parts is poor, a lot of R&D manpower is consumed, the quality control is difficult, and it is not conducive to cost reduction. On the other hand, as the heat dissipation wattage increases, the size and the volume of the fins need to be enlarged, which makes transportation and assembly more difficult, and the design of the flow channel seal is also more complicated.

Therefore, there is a need of providing a modular radiator assembly and an air-to-liquid cooling cabinet using the same to have the modular radiator assembly to be integrated and minimized, so that different numbers of modular radiator assemblies allows to be installed according to the customer's heat dissipation wattage requirements, thereby shortening the development time of the radiator, reducing the product cost and the development cost, and obviating the drawbacks encountered from the prior arts.

### SUMMARY OF THE INVENTION

It is an object of the present disclosure to provide a modular radiator assembly and an air-to-liquid cooling cabinet using the same to have the modular radiator assembly to be integrated and minimized, so that different numbers of modular radiator assemblies allows to be installed according to the customer's heat dissipation wattage requirements, thereby shortening the development time of the radiator and reducing the product cost and the development cost.

It is another object of the present disclosure to provide a modular radiator assembly and an air-to-liquid cooling cabinet using the same. A plurality of modular radiator assemblies allow being installed into a plurality of mounting bases on the rear panel of the air-to-liquid cooling cabinet in a simple and fast manner and spatially corresponding to the heat exchanger module in the cabinet to realize the application of air-assisted liquid cooling cabinets. Each modular radiator assembly includes a heat exchanger module arranged obliquely in the housing and cooperated with the upper fan set and the lower fan set to form a closed flow channel in the accommodation space of the housing, so as to reduce the flow resistance in the limited space. In order to maximize the heat dissipation capacity within the limited height of the accommodation space, the heat exchanger module is designed to have an inclination angle relative to the lower wall of the housing, and the upper fan set is designed to have another inclination angle relative to the lower fan set. In that, the airflow flows through the large bottom and top surfaces of the heat exchanger module, allowing the modular radiator assembly to further increase the number of fans and increase the maximum airflow rate. The tilted heat exchanger module can be fixed to the two lateral walls of the housing through the sheet metal on both sides. The upper fan set and the lower fan set can be fixed to the two lateral walls of the housing through fan sheet metal that is pre-bent to a designed angle. In addition, when the relative inclination angle of the upper fan set and the lower fan set is adjusted, it allows to add a guiding plate between the heat exchanger module and the upper fan set to optimize the closed flow channel. In this way, each modular radiator assembly can optimize the heat dissipation efficiency of the heat exchanger module within a limited space height, and each modular radiator assembly has a heat dissipation capacity of 20 kW to 40 kW. When the modular radiator assemblies are used in an air-to-liquid cooling cabinet with air-assisted liquid cooling, the number of installed radiator assemblies can be adjusted based on the requirements for heat dissipation capacity. Each modular radiator assembly is further connected to the coolant distribution unit (CDU) to complete the installation. It facilitates to increases the flexibility of use, simplifies the product line and increase the product quality. The present disclosure includes the industrial applicability and the inventive steps.

In accordance with an aspect of the present disclosure, a modular radiator assembly is provided and includes a housing, a heat exchanger module, an upper fan set and a lower fan set. The housing includes an air inlet, an air outlet, an upper wall, a lower wall and two lateral walls, wherein the upper wall and the lower wall are opposite to each other, the two lateral walls are connected between the upper wall and the lower wall, respectively, the upper wall, the lower wall and the two lateral walls are collaboratively configured to form an accommodation space, and the accommodation space is in communication between the air inlet and the air outlet. The heat exchanger module is connected to the upper wall, the lower wall and the two lateral walls, and accommodated in the accommodation space obliquely relative to the lower wall. The upper fan set and the lower fan set are disposed between the upper wall and the lower wall, respectively, connected between the two lateral walls, and arranged adjacent to the air inlet or the air outlet, wherein the upper fan set is arranged adjacent to the upper wall, the lower fan set is arranged adjacent to the lower wall, and the upper fan set is inclined at a first angle relative to the lower fan set and connected between the two lateral walls, wherein an airflow generated by the upper fan set and the lower fan set is inhaled through the air inlet, flows through the heat exchanger module, and is discharged from the air outlet.

In an embodiment, the heat exchanger module includes a main body, a hot water inflow tube and a cold water outflow tube, the hot water inflow tube and the cold water outflow tube are arranged at a rear end of the main body and disposed adjacent to the air outlet, wherein the upper fan set and the lower fan set are located at a front end of the main body and disposed adjacent to the air inlet, and the rear end of the main body is connected to the lower wall.

In an embodiment, the lower fan set is arranged vertically relative to the lower wall of the housing and connected between the two lateral walls of the housing, and the first angle is ranged from 90° to 180°.

In an embodiment, the modular radiator assembly further includes a guiding plate connected between the front end of the main body and an upper edge of the upper fan set, and connected between the two lateral walls of the housing.

In an embodiment, the heat exchanger module includes a main body, a hot water inflow tube and a cold water outflow tube, the hot water inflow tube and the cold water outflow tube are arranged at a front end of the main body and disposed adjacent to the air inlet, wherein the upper fan set and the lower fan set are located at a rear end of the main body and disposed adjacent to the air outlet, and the rear end of the main body is connected to the lower wall.

In an embodiment, the upper fan set and the lower fan set are arranged vertically relative to the lower wall of the housing and connected between the two lateral walls of the housing.

In an embodiment, the main body is tilted and received in the accommodation space at a second angle, wherein the second angle is ranged from 20° to 45°.

In an embodiment, the airflow generated by the upper fan set and the lower fan flows through the main body from a bottom surface of the main body, and then is discharged out of the main body from a top surface of the main body.

In an embodiment, the hot water inflow tube and the cold water outflow tube of the heat exchanger module are further connected to a coolant distribution unit.

In an embodiment, the hot water inflow tube of the heat exchanger module is located above the cold water outflow tube of the heat exchanger module.

In an embodiment, a closed flow channel is formed between the upper fan set, the lower fan set and the heat exchanger module, and the closed flow channel is located in the accommodation space of the housing.

In an embodiment, the airflow generated by the upper fan set and the lower fan set flows through the heat exchanger module from a bottom surface of the heat exchanger module and then is discharged out of the heat exchanger module from a top surface of the heat exchanger module.

In an embodiment, the upper fan set and the lower fan set are pre-installed on a fan sheet metal, and the fan sheet metal is mounted on the two lateral walls of the housing.

In an embodiment, the fan sheet metal is bent at the first angle, so that the upper fan set is inclined at the first angle relative to the lower fan set and is connected between the two lateral walls, wherein the first angle is ranged from 90° to 180°.

In an embodiment, the upper fan set and the lower fan set respectively comprise a plurality of fans, and the plurality of fans are detachably disposed on the fan sheet metal.

In accordance with another aspect of the present disclosure, an air-to-liquid cooling cabinet is provided and includes a side panel and a plurality of modular radiator assemblies. The side panel is disposed and extended along a first direction. The plurality of modular radiator assemblies are arranged on the side panel along the first direction or/and a second direction, and run through the side panel along a third direction, wherein the first direction, the second direction and the third direction are perpendicular to each other, wherein each of the plurality of modular radiator assemblies is detachably disposed on the side panel and includes a housing, a heat exchanger module, an upper fan set and a lower fan set. The housing includes an air inlet, an air outlet, an upper wall, a lower wall and two lateral walls, wherein the upper wall and the lower wall are opposite to each other, the two lateral walls are connected between the upper wall and the lower wall, respectively, the upper wall, the lower wall and the two lateral walls are collaboratively configured to form an accommodation space, and the accommodation space is in communication between the air inlet and the air outlet. The heat exchanger module is connected to the upper wall, the lower wall and the two lateral walls, and accommodated in the accommodation space obliquely relative to the lower wall. The upper fan set and the lower fan set are disposed between the upper wall and the lower wall, respectively, connected between the two lateral walls, and arranged adjacent to the air inlet or the air outlet, wherein the upper fan set is arranged adjacent to the upper wall, the lower fan set is arranged adjacent to the lower wall, and the upper fan set is inclined at a first angle relative to the lower fan set and connected between the two lateral walls, wherein an airflow generated by the upper fan set and the lower fan set is inhaled through the air inlet, flows through the heat exchanger module, and is discharged from the air outlet.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a structural perspective view illustrating a modular radiator assembly according to a first embodiment of the present disclosure;

FIG. 2 is a structural exploded view illustrating the modular radiator assembly according to the first embodiment of the present disclosure;

FIG. 3 is a cross-section view the modular radiator assembly according to the first embodiment of the present disclosure;

FIG. 4 is a structural perspective view illustrating an air-to-liquid cooling cabinet using the modular radiator assemblies according to the first embodiment of the present disclosure;

FIG. 5 is a front view illustrating the air-to-liquid cooling cabinet using the modular radiator assemblies according to the first embodiment of the present disclosure;

FIG. 6 is a structural perspective view illustrating a modular radiator assembly according to a second embodiment of the present disclosure;

FIG. 7 is a structural exploded view illustrating the modular radiator assembly according to the second embodiment of the present disclosure;

FIG. 8 is a cross-section view the modular radiator assembly according to the second embodiment of the present disclosure;

FIG. 9 is a structural perspective view illustrating an air-to-liquid cooling cabinet using the modular radiator assemblies according to the second embodiment of the present disclosure;

FIG. 10 is a front view illustrating the air-to-liquid cooling cabinet using the modular radiator assemblies according to the second embodiment of the present disclosure;

FIG. 11 is a structural perspective view illustrating a modular radiator assembly according to a third embodiment of the present disclosure;

FIG. 12 is a structural exploded view illustrating the modular radiator assembly according to the third embodiment of the present disclosure; and

FIG. 13 is a cross-section view the modular radiator assembly according to the third embodiment of the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “upper,” “lower,” “front,” “rear,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, “and/or” and the like may be used herein for including any or all combinations of one or more of the associated listed items.

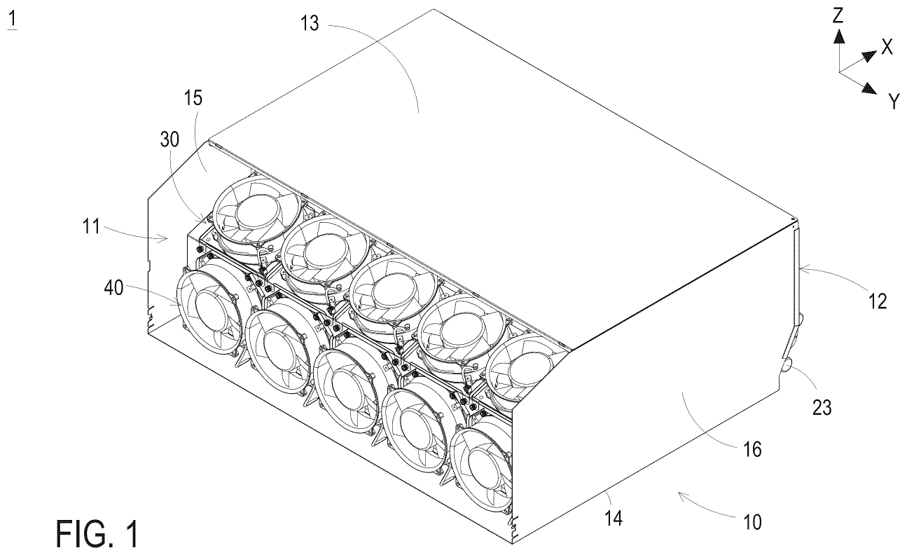

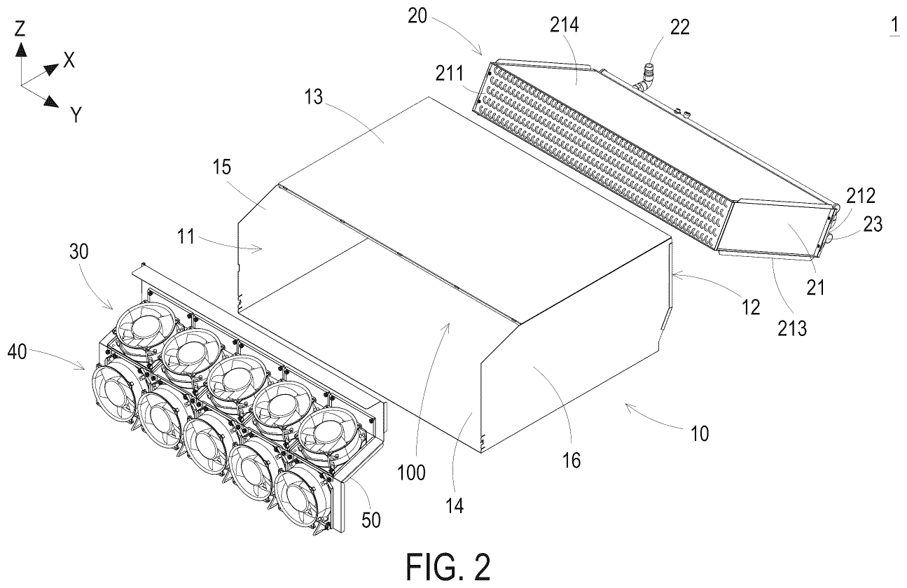

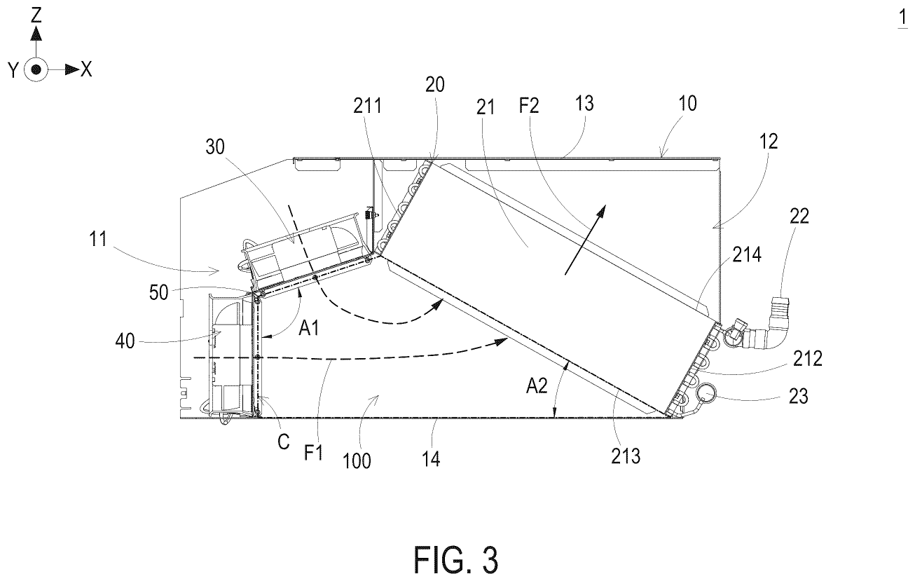

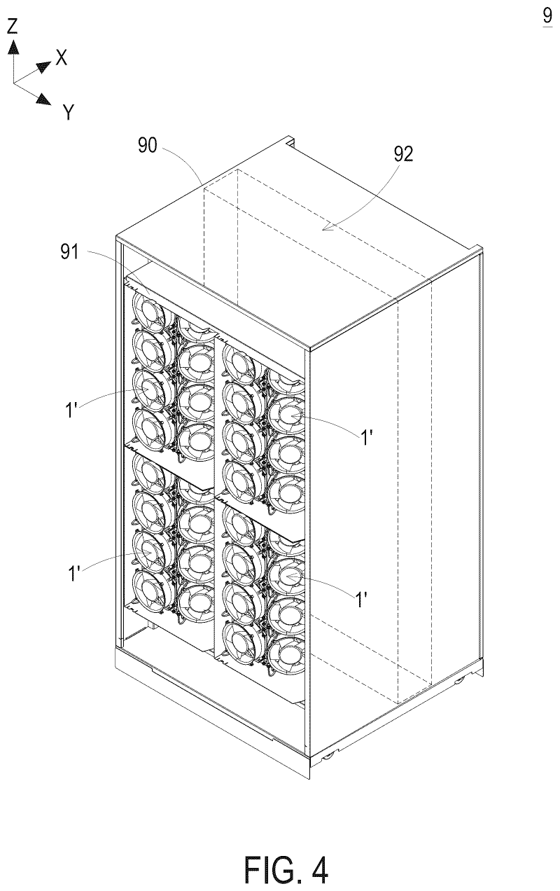

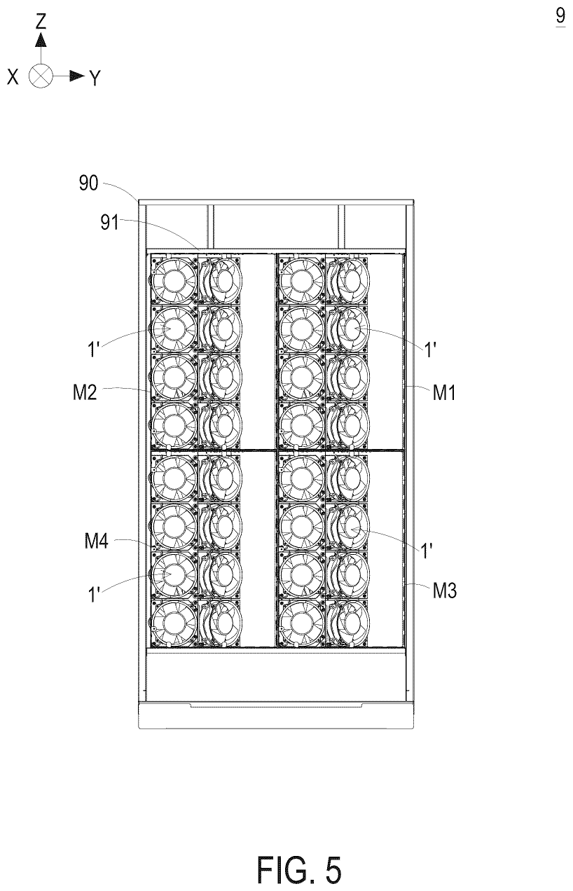

FIG. 1 is a structural perspective view illustrating a modular radiator assembly according to a first embodiment of the present disclosure. FIG. 2 is a structural exploded view illustrating the modular radiator assembly according to the first embodiment of the present disclosure. FIG. 3 is a cross-section view the modular radiator assembly according to the first embodiment of the present disclosure. FIG. 4 is a structural perspective view illustrating an air-to-liquid cooling cabinet using the modular radiator assemblies according to the first embodiment of the present disclosure. FIG. 5 is a front view illustrating the air-to-liquid cooling cabinet using the modular radiator assemblies according to the first embodiment of the present disclosure. Please refer to FIG. 1 to FIG. 5. In the embodiment, the present disclosure provides a modular radiator assembly 1 and an air-to-liquid cooling cabinet 9 using the same. A plurality of modular radiator assemblies 1 allow being installed into a plurality of mounting bases on the rear panel 91 of the air-to-liquid cooling cabinet 9 in a simple and fast manner to realize the application of air-assisted liquid cooling (AALC) cabinets. In the embodiment, the modular radiator assembly 1 includes a housing 10, a heat exchanger module 20, an upper fan set 30 and a lower fan set 40. The housing 10 includes an air inlet 11, an air outlet 12, an upper wall 13, a lower wall 14 and two left and right lateral walls 15, 16. The upper wall 13 and the lower wall 14 are opposite to each other. The two lateral walls 15, 16 are connected between the upper wall 13 and the lower wall 14, respectively. The upper wall 13, the lower wall 14 and the two lateral walls 15, 16 are collaboratively configured to form an accommodation space 100, and the accommodation space 100 is in communication between the air inlet 11 and the air outlet 12. The heat exchanger module 20 is connected to the upper wall 13, the lower wall 14 and the two lateral walls 15, 16, and a main body 21 of the heat exchanger module 20 is accommodated in the accommodation space 100 obliquely relative to the lower wall 14 of the housing 10. The upper fan set 30 and the lower fan set 40 are disposed between the upper wall 13 and the lower wall 14, respectively, connected between the two lateral walls 15, 16, and arranged adjacent to the air outlet 12. In the embodiment, the upper fan set 30 is arranged adjacent to the upper wall 13, the lower fan set 40 is arranged adjacent to the lower wall 14, and the upper fan set 30 is inclined at a first angle A1 relative to the lower fan set 40 and connected between the two lateral walls 15, 16. In the embodiment, an airflow generated by the upper fan set 30 and the lower fan set 40 is inhaled through the air inlet 11, flows through the heat exchanger module 20, and is discharged from the air outlet 12.

In the embodiment, the heat exchanger module 20 includes a main body 21, a hot water inflow tube 22 and a cold water outflow tube 23. The hot water inflow tube 22 and the cold water outflow tube 23 are arranged at a rear end 212 of the main body 21 and disposed adjacent to the air outlet 12. Preferably but not exclusively, the hot water inflow tube 22 of the heat exchanger module 20 is located above the cold water outflow tube 23 of the heat exchanger module 20. Preferably but not exclusively, in an embodiment, the metal sheets on both lateral sides of the main body 21 are fixed to the two lateral walls 15, 16 of the housing 10 by screws or other means. Preferably but not exclusively, in the embodiment, the main body 21 of the heat exchanger module 20 is tilted and received in the accommodation space 100 at a second angle A2 of 30°. In other embodiments, the second angle A2 is ranged from 20° to 45°. In the embodiment, the upper fan set 30 and the lower fan set 40 are located at a front end 211 of the main body 21 and disposed adjacent to the air inlet 11. The rear end 212 of the main body 21 is connected to the lower wall 14. In the embodiment, each of the upper fan set 30 and the lower fan set 40 includes five fans, which are detachably disposed on a fan sheet metal 50. The fan sheet metal 50 is assembled and fixed to the two lateral walls 15, 16 of the housing 10 by screws or other means, and connected to the front end 211 and the bottom surface 213 of the main body 21. In the embodiment, the fan sheet metal 50 is bent at the first angle A1 in advance, so that the upper fan set 30 is tilted relative to the lower fan set 40 at the first angle A1 of, for example, 110° and is connected to the two lateral walls 15, 16. In other embodiments, the first angle A1 is ranged from 90° to 180°. When the upper fan set 30 and the lower fan set 40 are connected to the lateral walls 15, 16 of the housing 10 through the fan sheet metal 50, the lower fan set 40 is vertically arranged relative to the lower wall 14 and connected between the two lateral walls 15, 16. The upper fan set 30 is tilted relative to the lower fan set 40 at the first angle A1 and connected between the two lateral walls 15, 16. The first angle A1 is ranged from 90° to 180°. Thereby, a closed flow channel C is formed between the upper fan set 30, the lower fan set 40 and the heat exchanger module 20, and the closed flow channel C is located in the accommodation space 100 of the housing 10. In the embodiment, the cold airflow F1 generated by the upper fan set 30 and the lower fan set 40 inhaled into the closed flow channel C through the air inlet 11, and the cold airflow F1 flows through the main body 21 of the heat exchanger module 20 from the bottom surface 213 of the main body 21 of the heat exchanger module 20, so as to perform heat exchange to form a hot airflow F2. The hot airflow F2 is discharged out of the heat exchanger module 20 from a top surface 214 of the main body 21 of the heat exchanger module 20. Since the cold airflow F1 and the hot airflow F2 have a large circulation area flowing through the main body 21, it helps to reduce flow resistance in the limited accommodation space 100, and enables the modular radiator assembly 1 to further increase the number of fans and increase the maximum airflow rate. Certainly, the present disclosure is not limited thereto.

In the embodiment, each modular radiator assembly 1 can optimized the heat dissipation efficiency of the heat exchanger module 20 within a limited space height of the accommodation space 100, and each modular radiator assembly 1 has a heat dissipation capacity of 20 kW to 40 kW. When the modular radiator assemblies 1 are used in an air-to-liquid cooling cabinet 9 with air-assisted liquid cooling, the number of installed radiator assemblies 1 can be adjusted based on the requirements for heat dissipation capacity. In the embodiment, the air-to-liquid cooling cabinet 9 includes a cabinet 90 and four modular radiator assemblies 1′. The structures of the four modular radiator assemblies 1′ are similar to that of the modular radiator assembly 1 shown in FIG. 1 to FIG. 2. The only difference is that the number of fans in the upper fan set 30 and the lower fan set 40 is respectively replaced with four. Please refer to FIG. 3 to FIG. 5. In the embodiment, four modular structures M1, M2, M3, M4 of the modular radiator assemblies 1′ allow being installed into the plurality of mounting bases on the rear panel 91 of the cabinet 90 in a simple and fast manner to realize the application of air-assisted liquid cooling cabinets. In the embodiment, the rear panel 91 of the cabinet 90 is disposed and extended along a first direction (i.e., the Z axial direction). In the embodiment, the four modular structures M1, M2, M3, M4 are flipped vertically to the ground and parallel to the first direction (i.e., the Z axial direction). The first modular structure M1 and the second modular structure M2 are stacked and arranged along the second direction (i.e., the Y axial direction), and the third modular structure M3 and the fourth modular structure M4 are arranged along the second direction (i.e., the Y axial direction). The first modular structure M1 and the third modular structure M3 are stacked and arranged along the first direction (i.e., the Z axial direction), and the second modular structure M2 and the fourth modular structure M4 are stacked and arranged along the first direction (i.e., the Z axial direction). In that, the four modular structures M1, M2, M3, M4 are disposed on the rear panel 91, and the modular radiator assemblies 1′ run through the rear panel 91 along a third direction (i.e., the X axial direction). The first direction, the second direction and the third direction are perpendicular to each other. After the four modular radiator assemblies 1′ are installed on the rear panels 91, the hot water inflow tube 22 and the cold water outflow tube 23 of each modular radiator assembly 1′ are connected to the coolant distribution unit (CDU) 92 to complete the installation. Since each modular radiator assembly 1′ can be minimized by the aforementioned arrangement, the air-to-liquid cooling cabinet 9 can be installed with different numbers of modular radiator assemblies 1′ according to the customer's heat dissipation wattage requirements. There is no need to design other heat sinks or radiators. Thereby, the development time of the radiator is shortened, and the product cost and the development cost are reduced sufficiently.

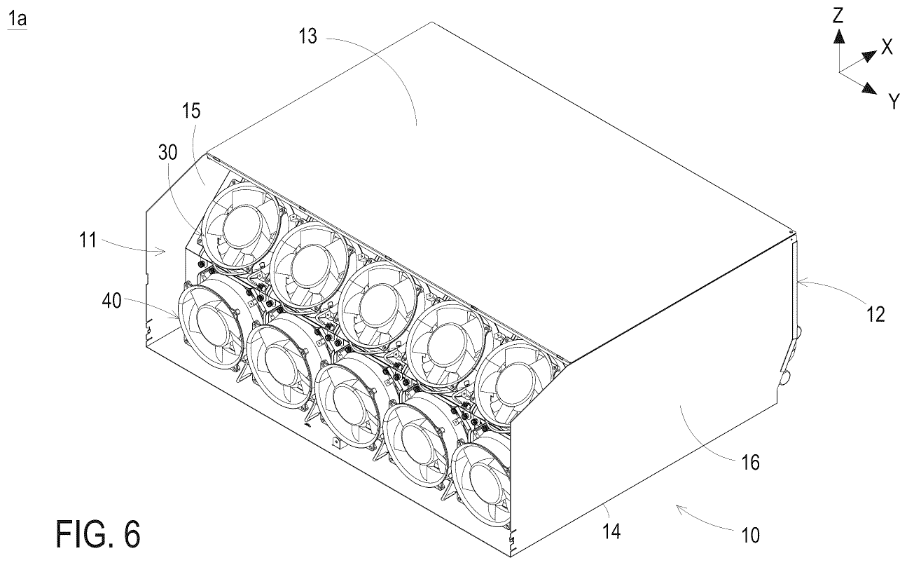

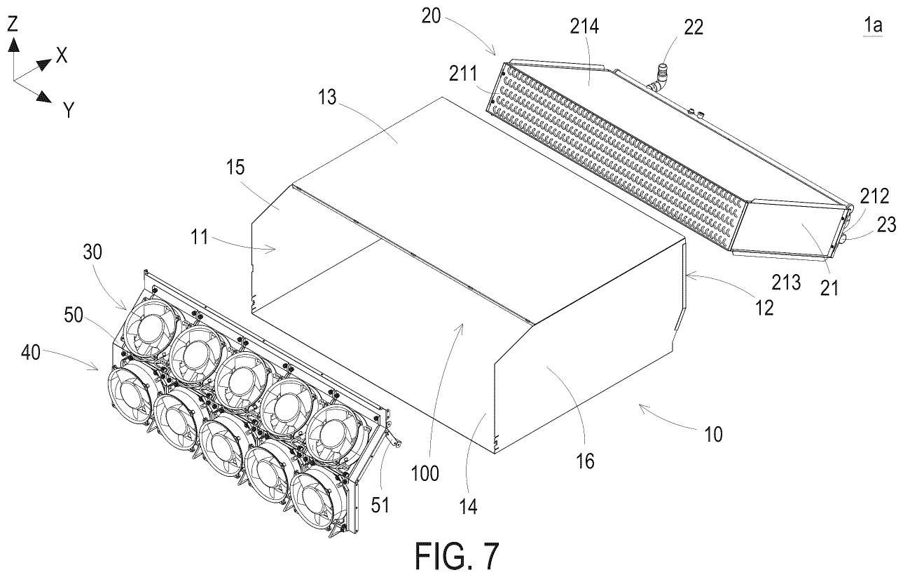

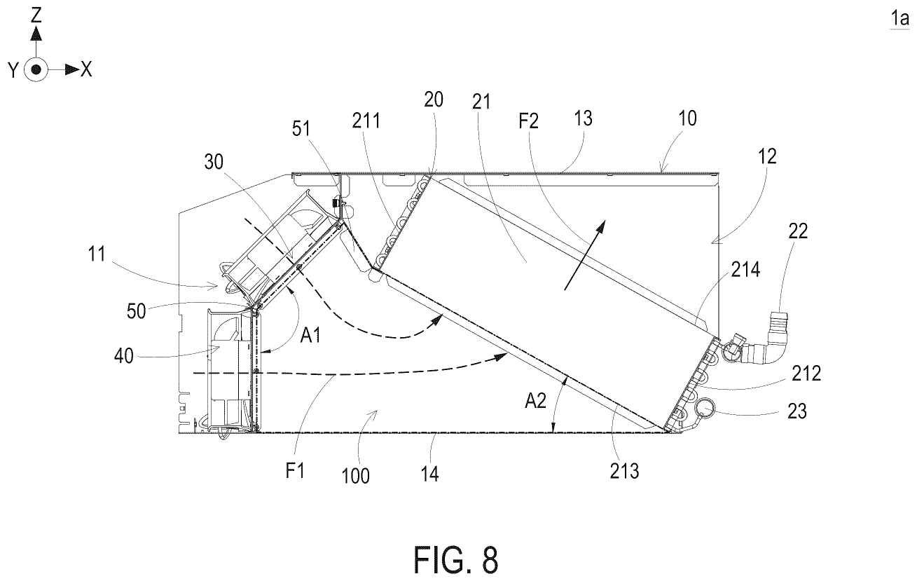

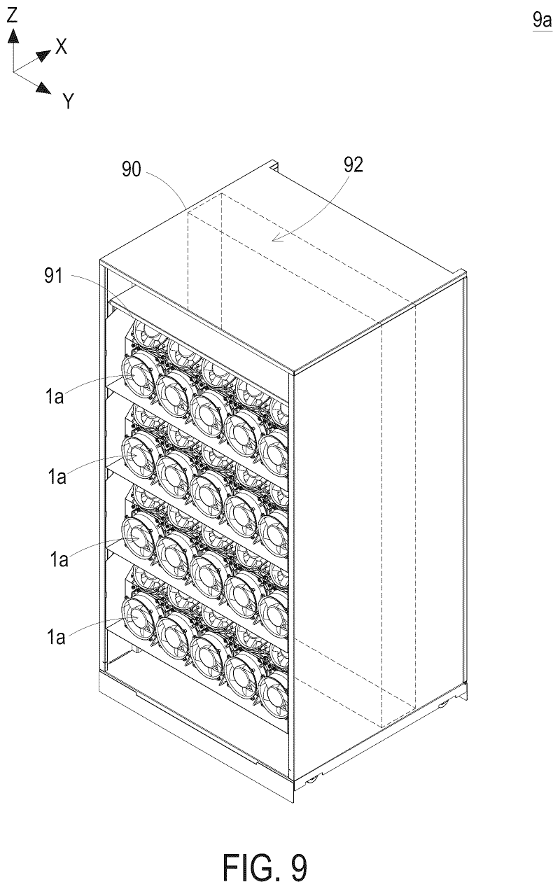

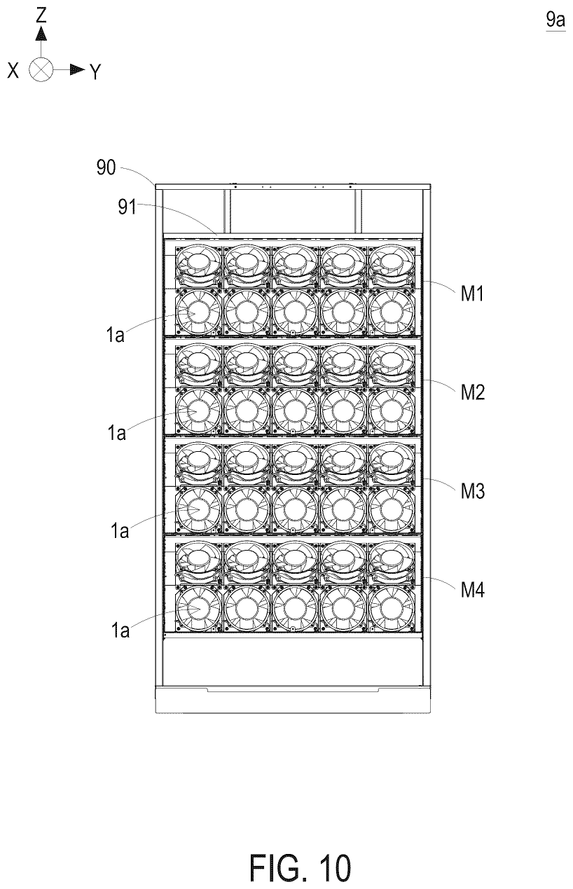

FIG. 6 is a structural perspective view illustrating a modular radiator assembly according to a second embodiment of the present disclosure. FIG. 7 is a structural exploded view illustrating the modular radiator assembly according to the second embodiment of the present disclosure. FIG. 8 is a cross-section view the modular radiator assembly according to the second embodiment of the present disclosure. FIG. 9 is a structural perspective view illustrating an air-to-liquid cooling cabinet using the modular radiator assemblies according to the second embodiment of the present disclosure. FIG. 10 is a front view illustrating the air-to-liquid cooling cabinet using the modular radiator assemblies according to the second embodiment of the present disclosure. In the embodiment, the structures, elements and functions of the air-to-liquid cooling cabinet 9a and the modular radiator assembly 1a are similar to those of the air-to-liquid cooling cabinet 9 and the modular radiator assembly 1, 1′ in FIG. 1 to FIG. 5, and are not redundantly described herein. In the embodiment, the modular radiator assembly 1a further includes a guiding plate 51. The guiding plate 51 is connected between the front end 211 of the main body 21 of the heat exchanger module 20 and an upper edge of the upper fan set 30, and connected between the two lateral walls 15, 16 of the housing 10. In the embodiment, the fan sheet metal 50 is bent at the first angle A1 in advance, so that the upper fan set 30 is inclined at the first angle A1 of 135° relative to the lower fan set 40 and is connected between the two lateral walls 15, 16. In the embodiment, the fan sheet metal 50 is further connected to the front end 211 and the bottom surface 213 of the main body 21 of the heat exchanger module 20 through the guiding plate 51. In this way, no matter how the first angle A1 of the upper fan set 30 is adjusted relative to the lower fan set 40, it facilitates the upper fan set 30 and the lower fan set 40, the guiding plate 51 and the heat exchanger module 20 collaborate to form a closed flow channel C through the connection of the guiding plate 51, and the closed flow channel C is optimized at the same time. In this way, each modular radiator assembly 1a can optimize the heat dissipation efficiency of the heat exchanger module 20 within a limited space height of the accommodation space 100, and each modular radiator assembly 1a has a heat dissipation capacity of 20 kW to 40 kW. When the modular radiator assemblies 1a are used in an air-to-liquid cooling cabinet 9 with air-assisted liquid cooling, the number of installed radiator assemblies 1a can be adjusted based on the requirements for heat dissipation capacity. Each modular radiator assembly 1a is further connected to the coolant distribution unit (CDU) 92 to complete the installation. Thereby, the development time and the product cost are reduced sufficiently.

In the embodiment, four modular structures M1, M2, M3, M4 are disposed horizontally. The upper fan set 30 and the lower fan set 40 of each modular radiator assembly 1a respectively include five detachable fans. Preferably but not exclusively, the first modular structure M1, the second modular structure M2, the third modular structure M3 and the fourth modular structure M4 are stacked and arranged along the first direction (i.e., the Z axial direction) in a simple and fast manner. In that, the four modular structures M1, M2, M3, M4 are disposed on the rear panel 91, and the modular radiator assemblies 1a run through the rear panel 91 along the third direction (i.e., the X axial direction). After the four modular radiator assemblies 1a are installed on the rear panels 91, the hot water inflow tube 22 and the cold water outflow tube 23 of each modular radiator assembly 1a are connected to the coolant distribution unit 92 to complete the installation. It facilitates to reduce the development time and the product cost sufficiently. Certainly, the number of fans in the upper fan set 30 and the lower fan set 40 and the arrangement of the modular radiator assemblies 1a are adjustable according to the practical requirements. The present disclosure is not limited thereto and not redundantly described hereafter.

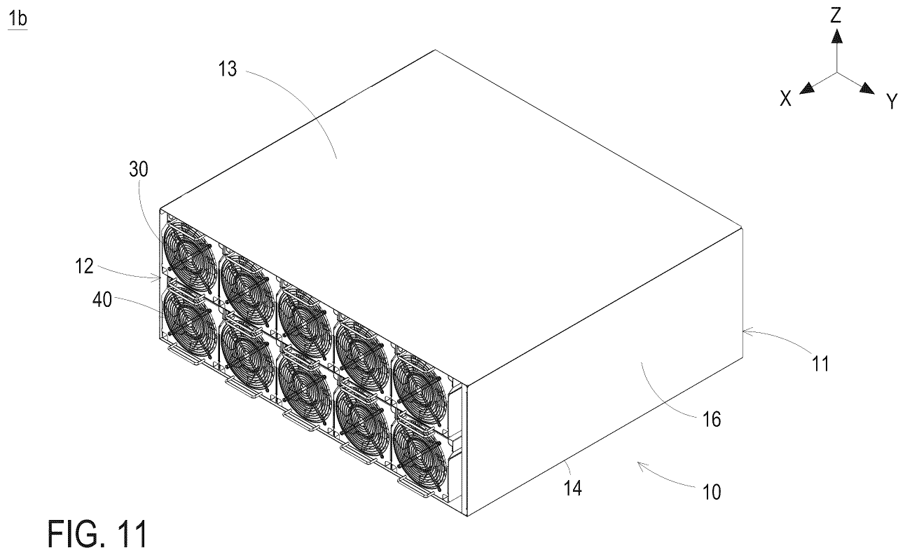

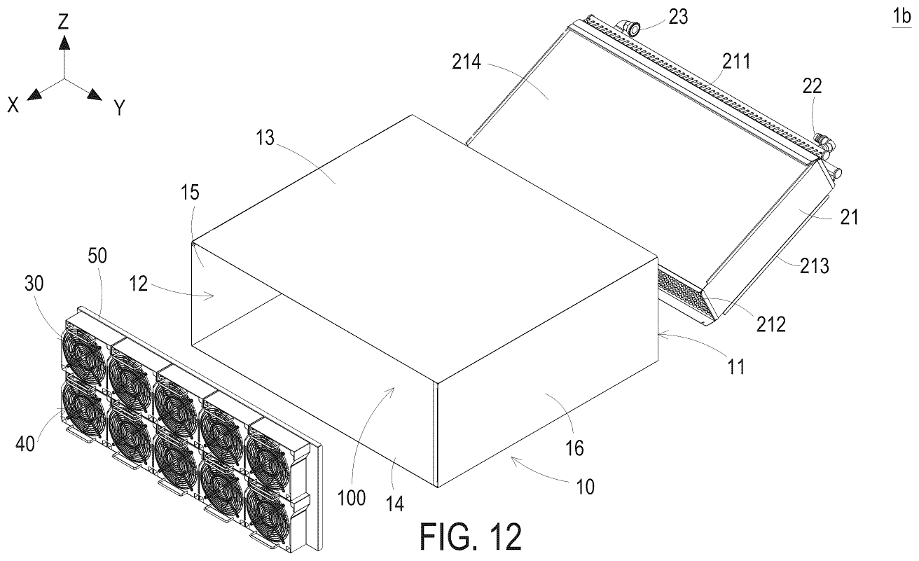

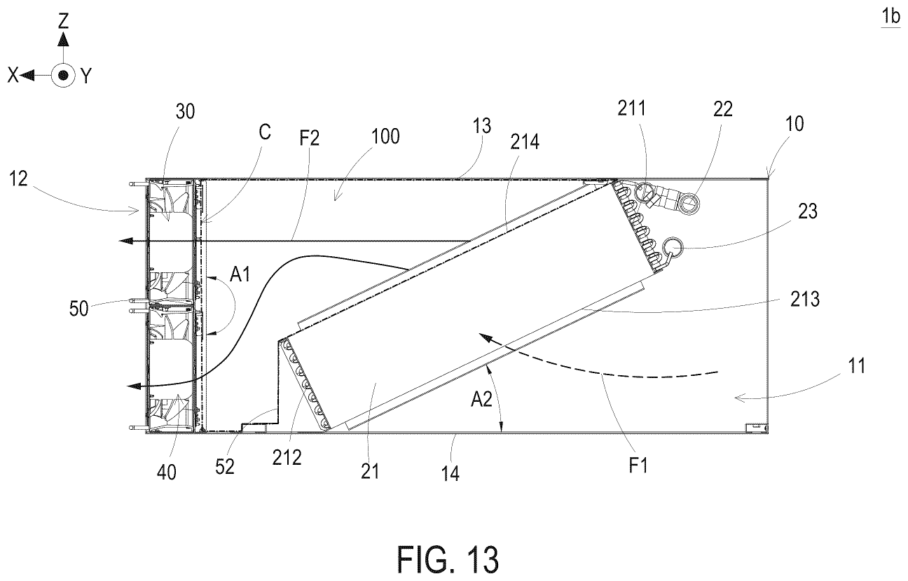

FIG. 11 is a structural perspective view illustrating a modular radiator assembly according to a third embodiment of the present disclosure. FIG. 12 is a structural exploded view illustrating the modular radiator assembly according to the third embodiment of the present disclosure. FIG. 13 is a cross-section view the modular radiator assembly according to the third embodiment of the present disclosure. In the embodiment, the structures, elements and functions of the modular radiator assembly 1b are similar to those of the modular radiator assembly 1 in FIG. 1 to FIG. 3, and are not redundantly described herein. Please refer to FIG. 11 to FIG. 13. In the embodiment, the modular radiator assembly 1b includes an upper fan set 30 and a lower fan set 40 arranged adjacent to the air outlet 12. The hot water inflow tube 22 and the cold water outflow tube 23 of the heat exchanger module 20 are disposed at the front end 211 of the main body 21 and arranged adjacent to the air inlet 11. The rear end 212 of the main body 21 is connected to the lower wall 14 of the housing 10. In addition, the main body 21 of the heat exchanger module 20 is tilted and received in the accommodation space 100 at a second angle A2 of 30°. In other embodiments, the second angle A2 is ranged from 20° to 45°. In the embodiment, the upper fan set 30 and the lower fan set 40 are arranged vertically relative to the lower wall 14 and connected between the two lateral walls 15, 16 of the housing 10. That is, the upper fan set 30 is tilted relative to the lower fan set 40 at the first angle A1 of, for example, 180°. The upper edge (i.e., one end of the top surface 214) of the rear end 212 of the main body 21 is connected to the lower wall 14 of the housing 10 through the connection plate 52. Thereby, a closed flow channel C is formed between the upper fan set 30, the lower fan set 40 and the heat exchanger module 20, and the closed flow channel C is located in the accommodation space 100 of the housing 10. In the embodiment, the cold airflow F1 generated by the upper fan set 30 and the lower fan set 40 inhaled into the closed flow channel C through the air inlet 11, and the cold airflow F1 flows through the main body 21 of the heat exchanger module 20 from the bottom surface 213 of the main body 21 of the heat exchanger module 20, so as to perform heat exchange to form a hot airflow F2. The hot airflow F2 is discharged in the closed flow channel C from a top surface 214 of the main body 21 of the heat exchanger module 20. Since the cold airflow F1 and the hot airflow F2 have a large circulation area flowing through the main body 21, it helps to reduce flow resistance in the limited accommodation space 100, and enables the modular radiator assembly 1b to further increase the number of fans and increase the maximum airflow rate. Certainly, the present disclosure is not limited thereto.

Notably, the aforementioned modular radiator assemblies 1, 1′, 1a, 1b can be arranged in the air-to-liquid cooling cabinets 9, 9a according to the practical requirements. The combination and the arrangement of the plurality of modular radiator assemblies 1, 1′, 1a, 1b in the air-to-liquid cooling cabinets 9, 9a are not limited to one single type. The present disclosure is not limited thereto and not redundantly described hereafter.

In summary, the present disclosure provides a modular radiator assembly and an air-to-liquid cooling cabinet using the same to have the modular radiator assembly to be integrated and minimized, so that different numbers of modular radiator assemblies allows to be installed according to the customer's heat dissipation wattage requirements, thereby shortening the development time of the radiator and reducing the product cost and the development cost. A plurality of modular radiator assemblies allow being installed into a plurality of mounting bases on the rear panel of the air-to-liquid cooling cabinet in a simple and fast manner and spatially corresponding to the heat exchanger module in the cabinet to realize the application of air-assisted liquid cooling cabinets. Each modular radiator assembly includes a heat exchanger module arranged obliquely in the housing and cooperated with the upper fan set and the lower fan set to form a closed flow channel in the accommodation space of the housing, so as to reduce the flow resistance in the limited space. In order to maximize the heat dissipation capacity within the limited height of the accommodation space, the heat exchanger module is designed to have an inclination angle relative to the lower wall of the housing, and the upper fan set is designed to have another inclination angle relative to the lower fan set. In that, the airflow flows through the large bottom and top surfaces of the heat exchanger module, allowing the modular radiator assembly to further increase the number of fans and increase the maximum airflow rate. The tilted heat exchanger module can be fixed to the two lateral walls of the housing through the sheet metal on both sides. The upper fan set and the lower fan set can be fixed to the two lateral walls of the housing through fan sheet metal that is pre-bent to a designed angle. In addition, when the relative inclination angle of the upper fan set and the lower fan set is adjusted, it allows to add a guiding plate between the heat exchanger module and the upper fan set to optimize the closed flow channel. In this way, each modular radiator assembly can optimize the heat dissipation efficiency of the heat exchanger module within a limited space height, and each modular radiator assembly has a heat dissipation capacity of 20 kW to 40 kW. When the modular radiator assemblies are used in an air-to-liquid cooling cabinet with air-assisted liquid cooling, the number of installed radiator assemblies can be adjusted based on the requirements for heat dissipation capacity. Each modular radiator assembly is further connected to the coolant distribution unit (CDU) to complete the installation. It facilitates to increases the flexibility of use, simplifies the product line and increase the product quality. The present disclosure includes the industrial applicability and the inventive steps.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A modular radiator assembly, comprising:
a housing, comprising an air inlet, an air outlet, an upper wall, a lower wall and two lateral walls, wherein the upper wall and the lower wall are opposite to each other, the two lateral walls are connected between the upper wall and the lower wall, respectively, the upper wall, the lower wall and the two lateral walls are collaboratively configured to form an accommodation space, and the accommodation space is in communication between the air inlet and the air outlet;
a heat exchanger module, connected to the upper wall, the lower wall and the two lateral walls, and accommodated in the accommodation space obliquely relative to the lower wall; and
an upper fan set and a lower fan set, disposed between the upper wall and the lower wall, respectively, connected between the two lateral walls, and arranged adjacent to the air inlet or the air outlet, wherein the upper fan set is arranged adjacent to the upper wall, the lower fan set is arranged adjacent to the lower wall, and the upper fan set is inclined at a first angle relative to the lower fan set and connected between the two lateral walls, wherein an airflow generated by the upper fan set and the lower fan set is inhaled through the air inlet, flows through the heat exchanger module, and is discharged from the air outlet.

2. The modular radiator assembly according to claim 1, wherein the heat exchanger module comprises a main body, a hot water inflow tube and a cold water outflow tube, the hot water inflow tube and the cold water outflow tube are arranged at a rear end of the main body and disposed adjacent to the air outlet, wherein the upper fan set and the lower fan set are located at a front end of the main body and disposed adjacent to the air inlet, and the rear end of the main body is connected to the lower wall.

3. The modular radiator assembly according to claim 2, wherein the lower fan set is arranged vertically relative to the lower wall of the housing and connected between the two lateral walls of the housing, and the first angle is ranged from 90° to 180°.

4. The modular radiator assembly according to claim 2, further comprising a guiding plate connected between the front end of the main body and an upper edge of the upper fan set, and connected between the two lateral walls of the housing.

5. The modular radiator assembly according to claim 2, wherein the main body is tilted and received in the accommodation space at a second angle, wherein the second angle is ranged from 20° to 45°.

6. The modular radiator assembly according to claim 2, wherein the airflow generated by the upper fan set and the lower fan flows through the main body from a bottom surface of the main body, and then is discharged out of the main body from a top surface of the main body.

7. The modular radiator assembly according to claim 2, wherein the hot water inflow tube and the cold water outflow tube of the heat exchanger module are further connected to a coolant distribution unit.

8. The modular radiator assembly according to claim 2, wherein the hot water inflow tube of the heat exchanger module is located above the cold water outflow tube of the heat exchanger module.

9. The modular radiator assembly according to claim 1, wherein the heat exchanger module comprises a main body, a hot water inflow tube and a cold water outflow tube, the hot water inflow tube and the cold water outflow tube are arranged at a front end of the main body and disposed adjacent to the air inlet, wherein the upper fan set and the lower fan set are located at a rear end of the main body and disposed adjacent to the air outlet, and the rear end of the main body is connected to the lower wall.

10. The modular radiator assembly according to claim 9, wherein the upper fan set and the lower fan set are arranged vertically relative to the lower wall of the housing and connected between the two lateral walls of the housing.

11. The modular radiator assembly according to claim 9, wherein the main body is tilted and received in the accommodation space at a second angle, wherein the second angle is ranged from 20° to 45°.

12. The modular radiator assembly according to claim 9, wherein the airflow generated by the upper fan set and the lower fan flows through the main body from a bottom surface of the main body, and then is discharged out of the main body from a top surface of the main body.

13. The modular radiator assembly according to claim 9, wherein the hot water inflow tube and the cold water outflow tube of the heat exchanger module are further connected to a coolant distribution unit.

14. The modular radiator assembly according to claim 9, wherein the hot water inflow tube of the heat exchanger module is located above the cold water outflow tube of the heat exchanger module.

15. The modular radiator assembly according to claim 1, wherein a closed flow channel is formed between the upper fan set, the lower fan set and the heat exchanger module, and the closed flow channel is located in the accommodation space of the housing.

16. The modular radiator assembly according to claim 1, wherein the airflow generated by the upper fan set and the lower fan set flows through the heat exchanger module from a bottom surface of the heat exchanger module and then is discharged out of the heat exchanger module from a top surface of the heat exchanger module.

17. The modular radiator assembly according to claim 1, wherein the upper fan set and the lower fan set are pre-installed on a fan sheet metal, and the fan sheet metal is mounted on the two lateral walls of the housing.

18. The modular radiator assembly according to claim 17, wherein the fan sheet metal is bent at the first angle, so that the upper fan set is inclined at the first angle relative to the lower fan set and is connected between the two lateral walls, wherein the first angle is ranged from 90° to 180°.

19. The modular radiator assembly according to claim 17, wherein the upper fan set and the lower fan set respectively comprise a plurality of fans, and the plurality of fans are detachably disposed on the fan sheet metal.

20. An air-to-liquid cooling cabinet, comprising:
a side panel, disposed and extended along a first direction, and
a plurality of modular radiator assemblies, arranged on the side panel along the first direction or/and a second direction, and running through the side panel along a third direction, wherein the first direction, the second direction and the third direction are perpendicular to each other, wherein each of the plurality of modular radiator assemblies is detachably disposed on the side panel and comprises:
a housing, comprising an air inlet, an air outlet, an upper wall, a lower wall and two lateral walls, wherein the upper wall and the lower wall are opposite to each other, the two lateral walls are connected between the upper wall and the lower wall, respectively, the upper wall, the lower wall and the two lateral walls are collaboratively configured to form an accommodation space, and the accommodation space is in communication between the air inlet and the air outlet;
a heat exchanger module, connected to the upper wall, the lower wall and the two lateral walls, and accommodated in the accommodation space obliquely relative to the lower wall; and
an upper fan set and a lower fan set, disposed between the upper wall and the lower wall, respectively, connected between the two lateral walls, and arranged adjacent to the air inlet or the air outlet, wherein the upper fan set is arranged adjacent to the upper wall, the lower fan set is arranged adjacent to the lower wall, and the upper fan set is inclined at a first angle relative to the lower fan set and connected between the two lateral walls, wherein an airflow generated by the upper fan set and the lower fan set is inhaled through the air inlet, flows through the heat exchanger module, and is discharged from the air outlet.
